(19) United States
(12) Patent Application Publication
(10) Pub. No.: US 2024/0345171 A1
(43) Pub. Date: Oct. 17, 2024

(54) STORAGE BATTERY CAPACITY ESTIMATION DEVICE AND SYSTEM

(71) Applicant: Nuvoton Technology Corporation Japan, Kyoto (JP)

(72) Inventor: Toshio MATSUKI, Kyoto (JP)

(21) Appl. No.: 18/750,798

(22) Filed: Jun. 21, 2024

Related U.S. Application Data
(63) Continuation of application No. PCT/JP2022/044461, filed on Dec. 1, 2022.

(30) Foreign Application Priority Data
Dec. 27, 2021 (JP) 2021-211856

(51) Int. Cl. G01R 31/388; G01R 31/36; G01R 31/367; G01R 31/392; H01M 10/44

(52) U.S. Cl. CPC G01R 31/388; G01R 31/3648; G01R 31/367; G01R 31/392; H01M 10/44

(57) ABSTRACT

An estimation device includes a measurement data storage storing measurement data items including: the first smoothed voltage value of a storage battery, a smoothed voltage change amount obtained by subtracting the first smoothed voltage value from the second smoothed voltage value of the storage battery, and a smoothed current value measured in synchronization with measurement of the first smoothed voltage value or the second smoothed voltage value, estimates an accumulated charge change amount using a trained estimation model that receives a first smoothed voltage value in a predetermined voltage range, a smoothed voltage change amount, and a smoothed current value, updates the trained estimation model using, as correct answer data, an accumulated charge change amount obtained by integrating current values measured during obtainment of the smoothed voltage change amount, and calculates the total sum of estimated accumulated charge change amounts in the predetermined voltage range to obtain the battery status.

### CROSS REFERENCE TO RELATED APPLICATIONS

This is a continuation application of PCT International Application No. PCT/JP2022/044461 filed on Dec. 1, 2022, designating the United States of America, which is based on and claims priority of Japanese Patent Application No. 2021-211856 filed on Dec. 27, 2021. The entire disclosures of the above-identified applications, including the specifications, drawings and claims are incorporated herein by reference in their entirety.

### FIELD

The present disclosure relates to a storage battery capacity estimation device and a system, and more particularly, to a storage battery capacity estimation device and a system that estimate the battery status of a storage battery.

### BACKGROUND

In recent years, devices using batteries such as storage batteries have been increasing in number. In order to safely use such devices, it is necessary to prevent batteries from running out of power, and even if a storage battery is in use, it is necessary to measure the correct capacity at the appropriate times.

As methods of obtaining the capacity (FCC) of a storage battery, there are a method of measuring the amount of charged charge by charging the storage battery from the state in which the storage battery ran out of charge to the full-charge state and a method of measuring a remaining capacity change amount (dSOC) and a charge change amount (dQ) each representing a change from the beginning to the end of a period, even if the storage battery has not run out of charge or reached the full-charge state, and dividing the charge change amount by the remaining capacity change amount.

The method of charging a storage battery from the state in which the storage battery ran out of charge to the full-charge state is a simple method. However, normally, storage batteries included in vehicles and other devices rarely run out of charge. Thus, the method is not an appropriate method of measuring the capacity at appropriate times.

The method of calculating the capacity (FCC) from the remaining capacity change amount (dSOC) and the charge change amount (dQ) requires remaining capacity (SOC) when calculating the remaining capacity change amount (dSOC). There are two ways of calculating the remaining capacity (SOC). One way of calculating the remaining capacity (SOC) is a method of measuring the open circuit voltage (OCV) of the storage battery and converting the open circuit voltage (OCV) into the remaining capacity (SOC). Since measurement of the open circuit voltage (OCV) is hampered by a change in the voltage resulting from at least one of charging or discharging (hereinafter, simply referred to as charging or discharging) of the storage battery, the open circuit voltage (OCV) cannot be directly measured. As relationship characteristics (the SOC-OCV curve) between the open circuit voltage (OCV) and the remaining capacity (SOC) changes due to degradation. Thus, even if a correct open circuit voltage (OCV) can be measured, the open circuit voltage (OCV) may not be able to be converted into the remaining capacity (SOC) correctly. Another way of calculating the remaining capacity (SOC) is a method of calculating a charge amount (Q) by integrating current values, dividing the charge amount (Q) by the capacity (FCC), and converting the result of the division into the remaining capacity (SOC) (a coulomb counting method). However, the method has the issue of occurrence of a cumulative error associated with measurement errors in current values when a coulomb counter performs long-time measurement. The method also has the issue of occurrence of circular calculation issue since the capacity (FCC) is used in calculating the final capacity (FCC). That is, the method of calculating the capacity (FCC) from the remaining capacity change amount (dSOC) and the charge change amount (dQ) is also not an appropriate method of measuring the capacity at the appropriate times.

In recent years, a machine learning estimation method of inputting the measured voltage or current value of a storage battery into an estimation model trained by machine learning and estimating the charging status of the storage battery from output from the estimation model has been suggested as a method of measuring the remaining capacity (SOC) and the capacity (FCC) of the storage battery (see Patent Literature (PTL) 1, 2, 3, and 4, for example). PTL 1 states: it is possible to calculate the remaining capacity (SOC) with high accuracy while avoiding an excessive calculation burden. In addition, PTL 2 states: it is possible to reduce the time and cost of generating an estimation model. PTL 3 states: it is possible to decrease a capacity estimation error caused by a load change. PTL 4 states: it is possible to reduce the cost of generating an estimation model, by using real-time machine learning.

In addition, a method of estimating the remaining capacity (SOC) and the capacity (FCC) of a storage battery, focusing on a differential characteristic curve when charging or discharging the storage battery has been suggested (see PTL 2, 4, 5, and 6, for instance). PTL 5 states: it is possible to calculate the capacity (FCC) from differential characteristics (dQ/dV characteristics and dV/dSOC characteristics) within a specific range of the remaining capacity (SOC). PTL 6 states: it is possible to avoid deterioration of the estimation accuracy due to differences in the ways of charging or discharging a storage battery. PTL 2 and PTL 4 also focus on the differential characteristics (dQ/dV characteristics).

### CITATION LIST

### Patent Literature

PTL 1: Japanese Unexamined Patent Application Publication No. 2006-300692

PTL 2: Japanese Unexamined Patent Application Publication No. 2020-106470

PTL 3: Japanese Unexamined Patent Application Publication No. 9-236641

PTL 4: Japanese Unexamined Patent Application Publication No. 2017-223537

PTL 5: Japanese Unexamined Patent Application Publication No. 2016-14588

PTL 6: Japanese Unexamined Patent Application Publication No. 2017-227539

### SUMMARY

### Technical Problem

However, in the techniques disclosed from PTL 1 to 6, input to and output from an estimation model include an open circuit voltage (OCV), remaining capacity (SOC), and capacity (FCC), and two or more estimation models are necessary. Thus, as the issues of the techniques, the characteristics of a storage battery in use cannot be obtained with high accuracy, and an estimation device cannot be implemented at a low cost.

In the machine learning estimation method disclosed in PTL 1, training data for use in generating an estimation model requires the remaining capacity (SOC) as correct answer data. If sufficient standing time is provided before and after charging or discharging, it is possible to measure an open circuit voltage (OCV) and convert the open circuit voltage (OCV) into the remaining capacity (SOC) correctly. However, since the sufficient standing time is necessary for each charging or discharging, the cost of preparing training data is not small. In addition, since the storage battery is left standing for sufficient time, the training data includes measurement data indicating a behavior different from a behavior when the storage battery is actually used, which results in the deterioration of the estimation accuracy as a drawback.

In addition, for the machine learning estimation method disclosed in PTL 1, two or more estimation models are prepared in advance for each usage environment of the storage battery and for each degradation state of the storage battery, and the estimation models are selectively used, which requires a high implementation cost. For a storage battery that takes a long time to be degraded, the cost of generating an estimation model is even higher. In addition, an increase in an estimation error due to false selection of an estimation model in estimating cannot be negligible. Furthermore, it is not possible to respond to unexpected characteristic changes in the storage battery. That is, as issues, the charging status (SOC) is used as the output of the estimation model, and many estimation models generated in consideration of the usage environments and degradation are necessary.

The machine learning estimation method disclosed in PTL 2 uses, as the estimation output of machine learning, a charge change amount characteristic (dQ/dV) and a voltage change amount characteristic (dV/dQ), which partially addresses the issues in PTL 1. However, an estimation model that can respond to various usage conditions and various states of a storage battery is required for the purpose of self-organization using a modular network self-organizing map algorithm. Thus, as with PTL 1, PTL 2 has the issue of the costs of generation and implementation of estimation models and the issue of deterioration of the accuracy attributed to selection of an estimation model. That is, PTL 2 has the issue of requiring many estimation models.

The method disclosed in PTL 3 partially addresses the issues in PTL 1 and 2, by inputting, into an estimation model, a measurement current value measured for each voltage within the output voltage range of a storage battery, to make it possible for the one estimation model to respond to the various usage states of the storage battery. However, as with PTL 1, PTL 3 also has the issue of requiring the correct remaining capacity (SOC) as labeled training data. In addition, many current values need to be input to the estimation model, and a large amount of characteristics leads to an increase in the size of the estimation model, which requires a large cost of implementation of an estimation device. Furthermore, in the estimation model disclosed in PTL 3, it is not possible to remove the effects of a voltage change due to the relaxation voltage of a storage battery, that is, a voltage attributed to Warburg impedance. Thus, a large error is caused depending of the state of the charge or discharge current of the storage battery. That is, PTL 3 has the issues: the remaining capacity (SOC) is used as the output of the estimation model, large amounts of characteristics are required, and the effects of the relaxation voltage cannot be removed.

In the method disclosed in PTL 4, a charge change amount (dQ) between two open circuit voltages (OCV) is input to an estimation model represented as an approximate expression, the remaining capacity (SOC) and the capacity (FCC) are used as the output of the estimation model, and the approximate expression is updated, which makes it possible to respond to the various usage states of a storage battery. In this way, the method disclosed in PTL 4 partially addresses the issues in PTL 1 and 2. However, as described above, it is difficult to obtain a correct open circuit voltage (OCV) during charging or discharging. In PTL 4, the open circuit voltage (OCV) is calculated using the internal resistance value of the storage battery. However, the internal resistance value easily changes during charging or discharging, which makes it difficult to achieve high estimation accuracy. That is, in PTL 4, using the open circuit voltage (OCV) as the output of the estimation model is considered as an issue.

In the method disclosed in PTL 5, a relationship between the full-charge capacity (FCC) and a voltage change (dV/dSOC) with respect to a remaining capacity change (dSOC) in each remaining capacity (SOC) and a relationship between the full-charge capacity (FCC) and a charge amount change (dQ/dV) with respect to the voltage are mapped (associated with one another) in advance. By using the mapped (associated) relationships, it is possible to estimate the capacity (FCC) even in a short charging or discharging time. However, PTL 5 has the drawback of requiring, as the input of the estimation model, the remaining capacity (SOC) difficult to calculate and the drawback of requiring to prepare, as correct answer data, the capacity (FCC) that requires a large cost to obtain, in generating a map. That is, in PTL 5, using the remaining capacity (SOC) and the capacity (FCC) as the input and output of the estimation model is considered as an issue.

The method disclosed in PTL 6 calculates the capacity (FCC) by performing fitting to two kinds of differential characteristic (dQ/dV) approximate curves and integrating differential characteristics (dQ/dV). Unlike PTL 1 and 2, PTL 6 does not require many approximate curves (equivalent to estimation models) and can deal with, for example, the degradation of a storage battery by fitting to the approximate curves. Thus, the cost of generating estimation models is small. However, the method disclosed in PTL 6 requires passing two or more differential characteristic (dQ/dV) peaks during charging or discharging. If the storage battery is used in a way that the peaks are not passed and if the storage battery has lost the differential characteristic (dQ/dV) peaks due to its degradation, the peaks cannot be measured any longer. In addition, the method in PTL 6 cannot be used in a storage battery having the characteristics of a small and linear change, in which measurement of differential characteristic (dQ/dV) peaks is difficult. That is, requiring the measurement of two differential characteristic (dQ/dV) peaks is considered as an issue.

As described above, the conventional techniques have the issue of not being able to estimate the remaining capacity (SOC) and capacity (FCC) of a storage battery with high accuracy or the issue of involving a large cost of implementation of an estimation device and a large cost of generation of an estimation model. The issues are attributed to, for example, difficulties in responding to complex behaviors associated with charging or discharging of the storage battery, various usage forms, and various degradation types, difficulties in estimating the open circuit voltage (OCV) and remaining capacity (SOC) of the storage battery being used, and difficulties in obtaining the capacity (FCC) as correct answer data included in machine learning training data.

In view of the above, the present disclosure provides a storage battery capacity estimation device and a system that can estimate the battery status of a storage battery with higher accuracy.

### Solution to Problem

A storage battery capacity estimation device according to one aspect of the present disclosure is a storage battery capacity estimation device that estimates the capacity of a storage battery. The storage battery capacity estimation device includes: a measurement data storage storing a plurality of measurement data items including: one or more first smoothed voltage values of the storage battery obtained by smoothing one or more voltage values measured during at least one of charging or discharging of the storage battery; a smoothed voltage change amount obtained by subtracting one of the one or more first smoothed voltage values from a second smoothed voltage value of the storage battery obtained by smoothing a voltage value further measured during the at least one of charging or discharging of the storage battery; one or more current values of the storage battery measured in synchronization with measurement of at least one of: the one of the one or more first smoothed voltage values or the second smoothed voltage value; and one or more smoothed current values obtained by smoothing the one or more current values; an accumulated-charge change amount estimator that estimates an accumulated charge change amount by using an estimation model that has learned through machine learning and that receives, as input to the estimation model that has learned, one or more first smoothed voltage values in a predetermined voltage range, a smoothed voltage change amount corresponding to one of the one or more first smoothed voltage values in the predetermined voltage range, and one or more smoothed current values; an accumulated-charge change amount machine learner that updates the estimation model by using, as input, the one or more first smoothed voltage values in the predetermined voltage range, the smoothed voltage change amount corresponding to the one of the one or more first smoothed voltage values, and the one or more smoothed current values out of the plurality of measurement data items and using, as correct answer data, an accumulated charge change amount obtained by integrating current values measured during obtainment of the smoothed voltage change amount; and a calculator that calculates the total sum of accumulated charge change amounts in the predetermined voltage range estimated by the accumulated-charge change amount estimator, and obtains the capacity of the storage battery according to the total sum calculated, the accumulated charge change amounts each being the accumulated charge change amount.

Here, for instance, the calculator calculates the total sum of the accumulated charge change amounts in the predetermined voltage range. The capacity (FCC) to be estimated can be calculated from the proportion of the total sum obtained by the calculation to the total sum obtained by calculation in the same voltage range for the storage battery with known capacity, and the known capacity.

Thus, the capacity (FCC) as the battery status of the storage battery is obtained by estimating and integrating the accumulated charge change amounts (dQ) with the use of the trained estimation model from smoothed voltage values measured during charging or discharging of the storage battery, the smoothed current value(s), and the smoothed voltage change amount (dV) calculated from two smoothed voltage values.

The training data does not include the remaining capacity (SOC), the open circuit voltage (OCV), or the full-charge capacity (FCC) of the storage battery which is difficult to obtain and calculate. Thus, the training data is obtained at a low cost. Then, even if a smoothed voltage change amount and an accumulated charge change amount are calculated from the results of calculation of voltage values during charging or discharging of the storage battery and corresponding accumulated charge amounts by using a coulomb counter, each of the above-mentioned change amounts indicates the amount of change caused within a relatively short time, which keeps error accumulation to a minimum. It is understood from the above that it is possible to lessen the effects of an error in the result of measurement by the current sensor and avoid the issue of error accumulation in the accumulated charge.

In addition, by using a low pass filter, it is possible to obtain measurement data in which the effects of the internal resistance of the storage battery and a relaxation voltage which may become error factors when estimating the accumulated charge change amount of the storage battery are suppressed. This is why the open circuit voltage (OCV) and the remaining capacity (SOC) which are very difficult to calculate during charging or discharging do not have to be used. Depending on the characteristics of the storage battery, the various states of the storage battery can be well learned by using, as input to the estimation model, current values and voltage values obtained via each of two or more low pass filters having different time constants. A suitable combination of low pass filters is determined from, for example, the implementation cost of the estimation device and the characteristics of the storage battery and how the storage battery is used, the examples of which include: one smoothed voltage value and two smoothed current values are used, or three smoothed voltage values and two smoothed current values are used. By using a suitable combination of low pass filters, it is possible to respond to estimation under various usage states with the use of one estimation model, which can reduce the generation cost of the estimation model and the implementation cost of the estimation device. Since juts one estimation model is sufficient, it is possible to avoid an issue of an increase in the estimation error due to false selection of an estimation model. Thus, the capacity (FCC) as the battery status of the storage battery can be estimated with higher accuracy.

Accordingly, by estimating the accumulated charge change amount with the use of the estimation model according to the estimation device and obtaining the battery status, the training data need not include data difficult to obtain and calculate. As such, the training data can be obtained at a low cost. Furthermore, since the effects of an error in the result of measurement by the current sensor are lessen and the issue of error accumulation in the accumulated charge can be avoided, the battery status of the storage battery can be estimated with higher accuracy. Furthermore, when a smoothed voltage and a smoothed current obtained as a result of smoothing by two or more low pass filters are used as input to the estimation model, one estimation model is sufficient, which enables reduction in the implementation cost of the estimation device and improvement of the accuracy at the same time.

For instance, in addition to a smoothed voltage value of the storage battery and a smoothed voltage change amount between the smoothed voltage value and another voltage value, previous measurement data items include a smoothed current value obtained by smoothing a current value measured in synchronization with the measurement of the smoothed voltage value and an accumulated charge change amount in a period during which a voltage change was seen. The accumulated-charge change amount machine learner is included that obtains, as training data, the smoothed voltage value, the smoothed current value, the voltage change amount, and the accumulated charge change amount which are included in the previous measurement data items and updates the estimation model by using the training data. The accumulated-charge change amount estimator estimates the accumulated charge change amount from each of: one or more voltage values in the predetermined voltage range and a voltage change amount corresponding to the one or more voltage values out of the measurement data items, by using the estimation model.

Since the estimation model is used while being updated, it is possible to follow a change in the characteristics of the storage battery. Thus, it is possible to respond not only to the degradation of the storage battery but also to the individual difference of the storage battery and the various usage states of the storage battery which were not present before the training. As such, it is possible to estimate the battery status of the storage battery with higher accuracy regardless of the degradation state and the usage state of the storage battery.

The storage battery capacity estimation device according to another aspect of the present disclosure further includes a degradation level calculator that estimates the degradation level of the storage battery from the proportion of the capacity of the storage battery to the initial capacity of the storage battery.

Since the capacity of the storage battery can be estimated with high accuracy, it is also possible to estimate the degradation level of the storage battery with high accuracy.

A system according to still another aspect of the present disclosure includes: the storage battery capacity estimation device described above; and a capacity management device that measures the plurality of measurement data items through at least one of charging or discharging of the storage battery. The storage battery capacity estimation device and the capacity management device are disposed at different locations, and the storage battery capacity estimation device obtains, via a communication network, the plurality of measurement data items obtained by the storage battery management device, and stores the plurality of measurement data items in the measurement data storage.

Since the battery status of the storage battery can be estimated from a remote location with high accuracy, it is possible to suppress the cost of having the configuration of the storage-battery-measurement-device side.

### Advantageous Effects

The present disclosure can achieve, for example, an estimation device capable of estimating the battery status of a storage battery with high accuracy.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a block diagram illustrating an example of a configuration of an estimation device according to an embodiment.

FIG. 2 illustrates an example of a configuration of a system according to Example 1.

FIG. 3 is a figure for conceptually explaining a method of estimating the charging status of a storage battery by an estimator according to Example 1.

FIG. 4 illustrates an example of a configuration of a charging status calculator according to Example 1.

FIG. 5 illustrates another example of the configuration of the charging status calculator according to Example 1.

FIG. 6 illustrates data before and after training proceeds through training processing performed by an accumulated-charge change amount machine learner according to Example 1.

FIG. 7 illustrates data before and after training proceeds through machine learning according to Example 1.

FIG. 8 illustrates another example of a configuration of the accumulated-charge change amount machine learner according to Example 1.

FIG. 9 illustrates still another example of the configuration of the accumulated-charge change amount machine learner according to Example 1.

FIG. 10 illustrates another example of the configuration of the system according to Example 1.

FIG. 11 illustrates an example of a configuration of a system according to Example 2.

FIG. 12 illustrates an example of a configuration when a charging status estimation device and a microcomputer that includes a storage battery measurer are at different locations.

FIG. 13 illustrates an example of a configuration when the charging status estimation device and a storage battery management device are at different locations.

### DESCRIPTION OF EMBODIMENT

The embodiments described below each indicates a specific example of the present disclosure. The numerical values, shapes, structural elements, steps, order of steps, and other details indicated in the embodiments described below are examples, and therefore do not intend to limit the present disclosure. In addition, among the structural elements described in the embodiments, those not recited in the independent claims are described as optional structural elements. In addition, it is possible to combine some of the descriptions of all the embodiments.

### Embodiment

An embodiment of the present disclosure is described below in detail with reference to the drawings.

### 1.1 Configuration of Estimation Device 10

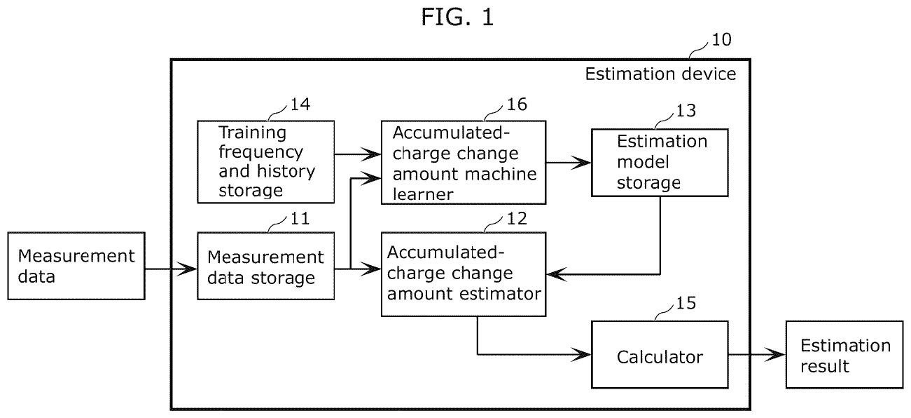

FIG. 1 is a block diagram illustrating an example of a configuration of estimation device 10 according to the embodiment.

Estimation device 10 is embodied as, for example, a computer including a processor (a microprocessor), memory, and a communication interface. On the basis of measurement data, estimation device 10 estimates the battery status indicating at least one of the capacity of a storage battery or the degradation level of the storage battery. Estimation device 10 is an example of each of a storage battery capacity estimation device and a storage battery degradation level estimation device.

It should be noted that the storage battery is capable of storing power and examples of the storage battery include a large-capacity storage battery and various secondary batteries such as a lithium-ion battery. In addition, the storage battery may include a combination of a plurality of small storage batteries. In addition, the storage battery may be two or more small storage batteries out of the plurality of small storage batteries included in the combination.

In the embodiment, as illustrated in FIG. 1, estimation device 10 includes measurement data storage 11, accumulated-charge change amount estimator 12, estimation model storage 13, training frequency and history storage 14, calculator 15, and accumulated-charge change amount machine learner 16. Here, estimation model storage 13 is not an essential element and may be provided outside estimation device 10. In this case, estimation device 10 may refer to and use external estimation model storage 13.

Measurement data storage 11 includes, for example, semiconductor memory. Measurement data storage 11 stores measurement data including one or more first smoothed voltage values and a smoothed voltage change amount, the one or more first smoothed voltage values being obtained as a result of smoothing, by the low pass filter of the storage battery, one or more voltage values measured during charging or discharging of the storage battery, the smoothed voltage change amount being obtained by subtracting one of the one or more first smoothed voltage values from a second smoothed voltage value obtained as a result of smoothing, by the low pass filter of the storage battery, a voltage value further measured. In addition, measurement data storage 11 stores measurement data indicating (i) an accumulated charge change amount obtained by integrating current values measured from the time point when the first smoothed voltage value was measured and until the time point when the second smoothed voltage value was measured and (ii) one or more smoothed current values obtained as a result of smoothing, by the low pass filter, one or more current values of the storage battery measured in synchronization with at least one of the first smoothed voltage value or the second smoothed voltage value. It should be noted that the first smoothed voltage value may be a voltage value obtained before the second smoothed voltage value is obtained or a voltage value obtained after the second smoothed voltage value is obtained.

Here, the measurement data may indicate a measured quantity measured when the storage battery is actually charged or discharged or may indicate a measured quantity generated and measured through simulation using an equivalent circuit of the storage battery.

In addition, the voltage of each part of the storage battery may be affected by the temperature at the measurement time point and a time period required for a voltage change. To improve the estimation accuracy, the measurement data may include other physical amounts measurable concurrently with the measured voltage value. For instance, the measurement data may include the temperature when the voltage is measured and the measurement duration.

Estimation model storage 13 includes, for example, a hard disk drive (HDD) or semiconductor memory, and stores an estimation model trained by machine learning.

An estimation model to be trained by machine learning may be, for example, a regression model for predicting a next value with respect to successive input values, a neural network model, a model that is a combination of decision trees, and, depending on the characteristics of the storage battery, a multiple linear regression analysis model (an approximate expression). Alternatively, the estimation model may be a classification type estimation model that can achieve necessary resolution.

In addition, ensemble learning, which combines two or more types of machine learning algorithms, may be used as a machine learning approach. For instance, one multiple linear regression analysis model cannot learn the voltage change amount and accumulated charge change amount of a storage battery having non-linear characteristics. Thus, a model that divides the usage voltage range of the storage battery into voltage regions and performs multiple linear regression analysis in each of the voltage regions may be trained by the ensemble learning. A model obtained by combining models trained by the ensemble learning may be used as the above estimation model.

It should be noted that if estimation model storage 13 is provided outside estimation device 10, estimation model storage 13 may be the storage of an external server or a cloud server.

Accumulated-charge change amount estimator 12 estimates accumulated charge change amount(s) (the amount(s) of change in the accumulated charge) by using the estimation model that has learned through machine learning and that receives, as input to the estimation model that has learned, one or more first smoothed voltage values in a predetermined voltage range, one or more voltage change amounts (the amounts of change in the voltage) corresponding to the one or more first smoothed voltage values, and one or more smoothed current values. It should be noted that accumulated-charge change amount estimator 12 may estimate the accumulated charge amount (the amount of accumulated charge) from data obtained by adding the temperature at the time of voltage measurement and the amount of change in the temperature to data to be input to accumulated-charge change amount estimator 12.

In the embodiment, using the trained estimation model, accumulated-charge change amount estimator 12 estimates accumulated charge change amounts from voltage values (e.g., 3.0 V) measured in steps of 0.1 V from 3.0 V, for example, in the voltage range of 3.0 V to 3.5 V, and the voltage change amounts (e.g., 0.1 V) of the voltage values. It should be noted that accumulated-charge change amount estimator 12 may perform estimation processing, using a GPU or a dedicated component such as a semiconductor intended for machine learning.

Accumulated-charge change amount machine learner 16 updates the estimation model stored in estimation model storage 13. Accumulated-charge change amount machine learner 16 obtains labeled training data from measurement data storage 11 and gradually updates coefficients within the estimation model in accordance with the training rate specified in advance.

Training frequency and history storage 14 includes an HDD or semiconductor memory. Training frequency and history storage 14 stores information for use in calculation by calculator 15 and stores, for example, the accumulated charge change amount estimated by accumulated-charge change amount estimator 12 and the voltage range and the training frequency in which/at which training was performed by accumulated-charge change amount machine learner 16.

Calculator 15 calculates the total sum of estimated accumulated charge change amounts in the predetermined voltage range and obtains the battery status on the basis of the calculated total sum.

In the embodiment, using accumulated charge change amounts estimated by accumulated-charge change amount estimator 12, calculator 15 calculates the total sum of accumulated charge change amounts in the predetermined voltage range. By doing so, calculator 15 can calculate accumulated charge in the predetermined voltage range and the battery status such as the capacity and the degradation level of the storage battery.

### 1.2 Effects of Embodiment

Unlike conventional techniques in which the battery status is obtained directly from the charge amount of a coulomb counter or the voltage value of a storage battery, estimation device 10 according to the embodiment calculates the charge change amount of the storage battery via the estimation model trained by machine learning, on the basis of the one or more smoothed voltage values of the storage battery, the one or more amounts of change in the one or more smoothed voltage values (one or more smoothed voltage change amounts), and one or more smoothed current values. Accordingly, using the trained estimation model, estimation device 10 according to the embodiment estimates accumulated charge change amount(s) from the smoothed voltage value(s) calculated from the measured values of voltages measured when the storage battery is charged or discharged, the smoothed voltage change amount(s), and the smoothed current value(s). In this way, estimation device 10 according to the embodiment can obtain the battery status of the storage battery as the result of estimation.

Here, a smoothed voltage change amount is used as input to the estimation model, and an accumulated charge change amount is the output from the estimation model. Thus, it is understood that the voltage change amount (dV) and the accumulated charge change amount (dQ) are mainly used as training data for the estimation model. Since the training data does not include the charging status (SOC) or the open circuit voltage (OCV) of the storage battery, the training data is obtained at a small cost. The accumulative error of the coulomb counter increases in proportion to the passage of time. Even if the voltage change amount and the accumulated charge change amount are calculated from the results of calculation using a coulomb counter of voltage values measured when the storage battery is charged or discharged and corresponding accumulated charge amounts, it takes a short time to obtain the voltage change amount, which makes it possible to reduce the effects of the accumulative error of the coulomb counter. It is understood from the above that it is possible to lessen the effects of an error in the result of measurement by a current sensor and avoid the issue of error accumulation in the accumulated charge. That is, by using the estimation model according to the embodiment, it is possible to lessen the effects of an error in the result of measurement by the current sensor. Furthermore, since the accumulated charge change amount can be measured simply and readily using the coulomb counter, training data can also be readily obtained, which is considered as an advantage.

Thus, by estimating the accumulated charge change amount from, for example, a smoothed voltage change amount with the use of the estimation model, and obtaining the battery status, there is no need to include, in the training data, the charging status (SOC) or the open circuit voltage (OCV) of the storage battery, which is difficult to obtain. Thus, it is possible to obtain the training data at a low cost. In addition, by using one or more smoothed voltage values and one or more smoothed current values, it is possible to suppress effects on the measurement of a change in the current during charging or discharging, and respond to the various usage states of the storage battery with the use of the same estimation model. Furthermore, since measurement data within a short period is used, the effects of an error in the result of measurement by the current sensor are lessen, and it is possible to avoid the issue of error accumulation in the accumulated charge. Thus, the battery status of the storage battery can be estimated with higher accuracy.

A system configuration including an estimation device that estimates, as the battery status of the storage battery, at least one of the capacity or degradation level of the storage battery is described below as Examples.

### Example 1

In Example 1, a case in which the battery status of the storage battery is the capacity of the storage battery is described. The capacity is also referred to as FCC and indicates the maximum amount of charge that can be stored in the storage battery.

### 2 Configuration of System According to Example 1

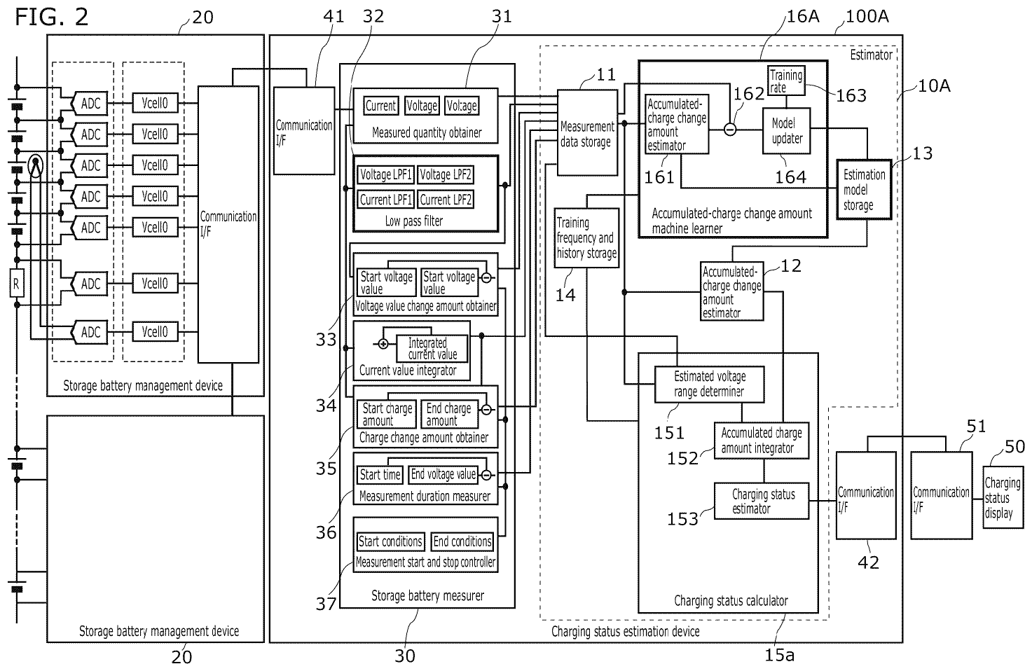

FIG. 2 illustrates an example of a configuration of a system according to Example 1.

As illustrated in FIG. 2, the system according to Example 1 includes charging status estimation device 100A, one or more storage battery management devices 20, and charging status display 50.

### 2.1 Storage Battery Management Device 20

Storage battery management device 20 charges or discharges the storage battery and obtains measurement data. In Example 1, storage battery management device 20 is in contact with or close to the storage battery, and measures the current flowing through the storage battery or voltages at both ends of the storage battery while charging or discharging the storage battery. Storage battery management device 20 may further measure the temperature of the storage battery. Storage battery management device 20 transmits the measured quantity such as a measured current value or a measured voltage value to charging status estimation device 100A via communication I/F communicably connected to a network.

Although it is stated in the above that storage battery management device 20 is in contact with or close to the storage battery, the location of storage battery management device 20 is not limited the example. The storage battery may be included in storage battery management device 20.

### 2.2 Charging Status Display 50

Charging status display 50 includes a display. Charging status display 50 obtains, via communication I/F51, the charging status of the storage battery estimated by charging status estimation device 100A, and displays the charging status on the display.

### 2.3 Charging Status Estimation Device 100A

Charging status estimation device 100A obtains the measured quantity such as the current value or the voltage value from storage battery management device 20. Charging status estimation device 100A estimates the charging status of the storage battery on the basis of the obtained measured quantity.

In Example 1, as illustrated in FIG. 2, charging status estimation device 100A includes storage battery measurer 30, estimator 10A, and communication I/F41 and communication I/F42 which are communicably connected to the network. Charging status estimation device 100A outputs the estimated charging status of the storage battery to communication I/F42.

### 2.3.1 Storage Battery Measurer 30

Storage battery measurer 30 obtains the measured quantity such as the current value or the voltage value and information such as information related to the measured quantity from storage battery management device 20 via communication I/F41.

For instance, as illustrated in FIG. 2, storage battery measurer 30 includes measured quantity obtainer 31, low pass filter 32, voltage value change amount obtainer 33, current value integrator 34, charge change amount obtainer 35, measurement duration measurer 36, and measurement start and stop controller 37.

Measured quantity obtainer 31 obtains, as the measured quantity, the current or the voltage measured by storage battery management device 20. Measured quantity obtainer 31 may store the obtained current value and voltage value in measurement data storage 11.

Low pass filter 32 includes one or more low pass filters. For instance, low pass filter 32 includes two low pass filters having different time constants, which are voltage low pass filter LPF1 and voltage low pass filter LPF2. Furthermore, low pass filter 32 includes two low pass filters having different time constants, which are current low pass filter LPF1 and current low pass filter LPF2. Low pass filter 32 smooths the measured quantity obtained by measured quantity obtainer 31 and stores the smoothed measured quantity in measurement data storage 11 of estimator 10A. It should be noted that low pass filter 32 may smooth the measurement data in measurement data storage 11 of estimator 10A and transmit the smoothed measurement data to accumulated-charge change amount estimator 12 of estimator 10A.

Voltage value change amount obtainer 33 obtains the amount of change in the smoothed voltage value (a voltage change amount) from start to stop of measurement by storage battery management device 20.

Current value integrator 34 calculates an integrated current value (an accumulated charge amount), which is a value obtained by integrating current values obtained by measured quantity obtainer 31. Current value integrator 34 may store the calculated integrated current value in measurement data storage 11.

Charge change amount obtainer 35 obtains a charge change amount (the amount of change in the charge) from start to stop of measurement by storage battery management device 20. In the example illustrated in FIG. 2, charge change amount obtainer 35 obtains the charge change amount indicating a change in the integrated current value (the accumulated charge amount), which is an integrated value of the current values that measured quantity obtainer 31 obtained from start to stop of measurement by storage battery management device 20. Charge change amount obtainer 35 may store the calculated charge change amount in measurement data storage 11.

Measurement duration measurer 36 measures, as a measurement duration, the time period from start to stop of measurement by storage battery management device 20. Measurement duration measurer 36 may store the calculated measurement duration in measurement data storage 11.

Measurement start and stop controller 37 makes a judgment as to whether to start or stop the measurement according to the time, the smoothed voltage, the current, and the smoothed current. For instance, measurement start and stop controller 37 identifies that storage battery management device 20 started measuring or stopped measuring, from, for example, the current value obtained by measured quantity obtainer 31 and the level of the smoothed voltage value calculated by voltage value change amount obtainer 33. In addition, while causing current value integrator 34 to calculate an integrated current value by an operation command, measurement start and stop controller 37 causes voltage value change amount obtainer 33 to obtain a voltage change amount and charge change amount obtainer 35 to obtain an accumulated charge change amount. It should be noted that measurement start and stop controller 37 may cause, by an operation command, voltage value change amount obtainer 33 to obtain the temperature, the time, and the current and to obtain a filtered voltage value and a filtered current value via low pass filter 32.

### 2.3.2 Estimator 10A

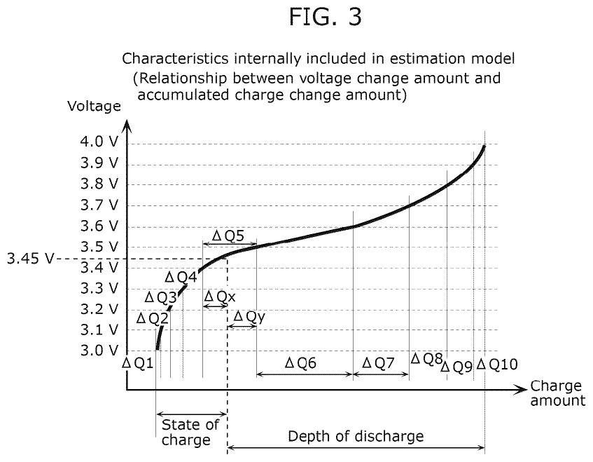

FIG. 3 is a figure for conceptually explaining a method of estimating the charging status of the storage battery by estimator 10A according to Example 1. FIG. 3 illustrates a graph representing an image of the characteristics of the storage battery internally included in an estimation model trained by machine learning under the conditions: a discharge termination voltage (the lowest voltage) of the storage battery of 3.0 V, an upper limit charging voltage (the highest voltage) of 4.0 V, and in a voltage range in steps of 0.1 V. Furthermore, FIG. 3 indicates that the present voltage of the storage battery is 3.45 V. It should be noted that FIG. 3 illustrates an example of steps of 0.1 V. However, the voltage width as steps is not limited to the steps of 0.1 V. The voltage widths need not be equal intervals and may be determined according to the characteristics of the storage battery or required estimation accuracy.

As illustrated in FIG. 2, estimator 10A includes measurement data storage 11, accumulated-charge change amount estimator 12, estimation model storage 13, training frequency and history storage 14, and charging status calculator 15a. Estimator 10A is an example of estimation device 10 in FIG. 1. It should be noted that the elements similar to those illustrated in FIG. 1 are assigned the same reference signs. Differences from the embodiment are mainly described below.

### 2.3.2.1 Accumulated-Charge Change Amount Estimator 12

Accumulated-charge change amount estimator 12 estimates accumulated charge change amount(s) by using the estimation model that has learned through machine learning and that receives, as input to the estimation model that has learned, one or more smoothed voltage values in a predetermined voltage range, one or more smoothed voltage change amounts corresponding to the one or more smoothed voltage values, and one or more smoothed current values. Here, the predetermined voltage range is determined by charging status calculator 15a, which is described later.

In Example 1, accumulated-charge change amount estimator 12 estimates accumulated charge change amount(s) from one or more smoothed voltage values in a voltage range determined by estimated voltage range determiner 151 of charging status calculator 15a, one or more smoothed voltage change amounts corresponding to the one or more smoothed voltage values, and one or more smoothed current values.

A more specific explanation is provided below with reference to FIG. 3. For instance, using the estimation model, accumulated-charge change amount estimator 12 estimates accumulated charge change amount ΔQ1 when the smoothed voltage changes from 3.0 V to 3.1 V. Then, using the estimation model, accumulated-charge change amount estimator 12 sequentially estimates accumulated charge change amount ΔQ2 when the smoothed voltage changes from 3.1 V to 3.2 V and accumulated charge change amount ΔQ3 when the smoothed voltage changes from 3.2 V to 3.3 V. Then, using the estimation model, accumulated-charge change amount estimator 12 estimates accumulated charge change amount ΔQ4 when the smoothed voltage changes from 3.3 V to 3.4 V. Since the present smoothed voltage of the storage battery is 3.45 V, accumulated-charge change amount estimator 12 estimates, using the estimation model, accumulated charge change amount ΔQx when the smoothed voltage changes from 3.4 V to 3.45 V. In this way, accumulated-charge change amount estimator 12 can estimate one or more accumulated charge change amounts from (i) one or more smoothed voltage values in the voltage range from the discharge termination voltage to the present smoothed voltage and (ii) one or more voltage change amounts corresponding to the one or more smoothed voltage values. Furthermore, by adding a smoothed current as input to the estimation model and then causing the estimation model to estimate, it is possible to estimate an accumulated charge change amount with high accuracy with the use of just one estimation model.

It should be noted that accumulated-charge change amount estimator 12 may estimate accumulated charge change amount(s) in a given voltage range, which means estimation is not limited to estimation of accumulated charge change amount(s) in the voltage range from the discharge termination voltage to the present voltage.

It should be noted that accumulated-charge change amount estimator 12 may perform preprocessing prior to the above estimation processing and perform post-processing after the above estimation processing.

### 2.3.2.2 Charging Status Calculator 15a

As illustrated in FIG. 2, charging status calculator 15a includes estimated voltage range determiner 151, accumulated charge amount integrator 152, and charging status estimator 153. It should be noted that charging status calculator 15a is a specific example of calculator 15 in the embodiment.

Estimated voltage range determiner 151 refers to the measurement data stored in measurement data storage 11 and determines in which one of voltage ranges accumulated charge change amount(s) are to be estimated. This enables accumulated-charge change amount estimator 12 to estimate the accumulated charge change amount(s) in each of one or more separate voltage ranges.

Accumulated charge amount integrator 152 calculates the total sum of accumulated charge change amounts in the predetermined voltage range.

In the example illustrated in FIG. 3, accumulated charge amount integrator 152 calculates the total sum of accumulated charge change amounts ΔQ1, ΔQ2, ΔQ3, ΔQ4, and ΔQx estimated by accumulated-charge change amount estimator 12. In addition, accumulated charge amount integrator 152 may calculate the total sum of accumulated charge change amounts ΔQ10, ΔQ9, ΔQ8, ΔQ7, ΔQ6, and ΔQy estimated by accumulated-charge change amount estimator 12.

Charging status estimator 153 calculates the charging status of the storage battery from the total sum calculated by accumulated charge amount integrator 152.

More specifically, charging status estimator 153 can calculate the capacity of the storage battery to be calculated, from (i) the proportion of the total sum of the accumulated charge change amounts in the predetermined voltage range, calculated by accumulated charge amount integrator 152, to the total sum of accumulated charge change amounts in the predetermined voltage range in the storage battery with known capacity and (ii) the known capacity of the storage battery. In the example illustrated in FIG. 3, charging status estimator 153 divides total sum ΔQsum1 of calculated accumulated charge change amounts ΔQ1, ΔQ2, ΔQ3, ΔQ4, and ΔQx by total sum ΔQsum2 of ΔQ1, ΔQ2, ΔQ3, ΔQ4, and ΔQx in the storage battery having capacity FCC2, and multiplies the result of the division by capacity FCC2. The result of the multiplication is obtained as the capacity of the storage battery.

As described above, charging status calculator 15a can calculate the capacity of the storage battery as the battery status.

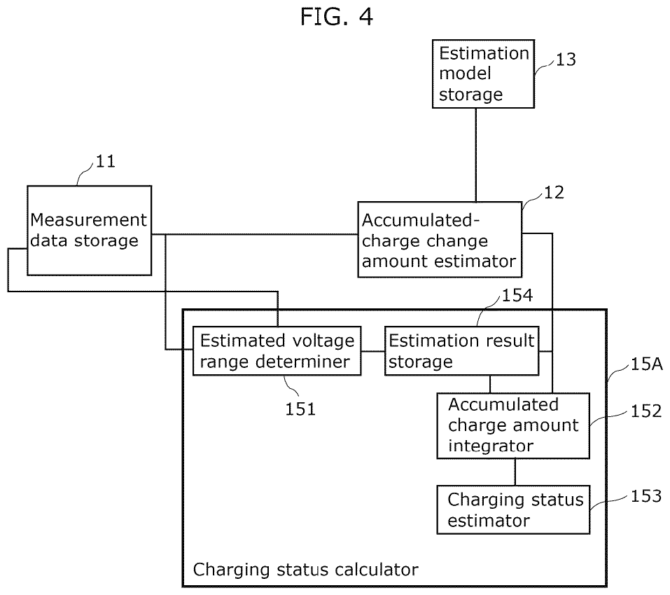

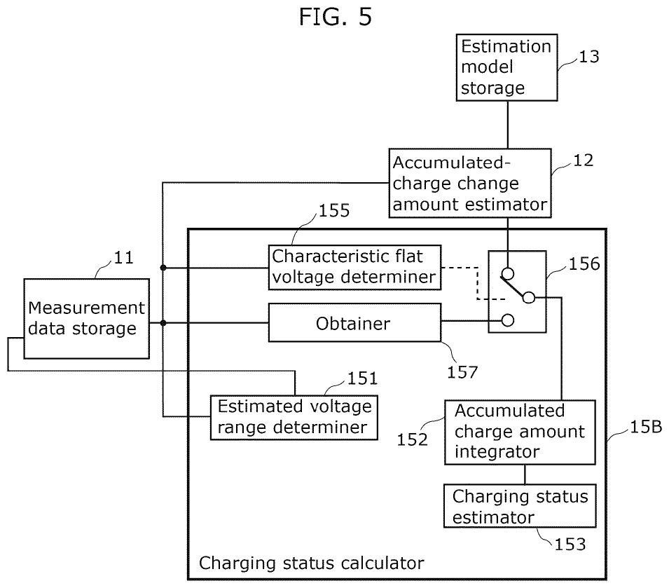

It should be noted that when there is no change in the surrounding state of the storage battery, the storage battery has a slow characteristic change. Thus, charging status calculator 15a need not successively use the results of estimation by accumulated-charge change amount estimator 12 and may reuse a previously obtained estimation result during a period with a slow characteristic change. In addition, in a characteristic region having a small voltage change amount relative to the accumulated charge change amount of the storage battery, the accuracy of estimation is in some cases higher when without using the estimation model. In such a case, an estimation method using another approach may be used. This enables charging status calculator 15a to reduce the load of the estimation processing by accumulated-charge change amount estimator 12. An example in this case is described with reference to FIGS. 4 and 5.

FIG. 4 illustrates an example of a configuration of charging status calculator 15A according to Example 1.

In terms of including estimation result storage 154, charging status calculator 15A in FIG. 4 has a configuration different from that of charging status calculator 15a in FIG. 2. It should be noted that the elements similar to those illustrated in FIG. 2 are assigned the same reference signs and detailed explanations are omitted.

Estimation result storage 154 includes semiconductor memory. Estimation result storage 154 stores the result of estimation by accumulated-charge change amount estimator 12. Estimation result storage 154 updates the result of the estimation by accumulated-charge change amount estimator 12 at predetermined timings. Thus, it is possible not only to suppress the estimation result stored in estimation result storage 154 from becoming obsolete but also to reduce the load of the processing by charging status calculator 15a and the load of the estimation processing by accumulated-charge change amount estimator 12.

FIG. 5 illustrates an example of a configuration of charging status calculator 15B according to Example 1.

In terms of including characteristic flat voltage determiner 155, selector 156, and obtainer 157, charging status calculator 15B in FIG. 5 has a configuration different from that of charging status calculator 15a in FIG. 2. It should be noted that the elements similar to those illustrated in FIG. 2 are assigned the same reference signs and detailed explanations are omitted.

Characteristic flat voltage determiner 155 determines whether the voltage range is a flat voltage range in which the storage battery has flat charging status characteristics. When determining that the voltage range is a flat voltage range in which the storage battery has flat charging status characteristics, characteristic flat voltage determiner 155 operates selector 156 so as not to use accumulated charge change amounts estimated by accumulated-charge change amount estimator 12 in the flat voltage range.

Selector 156 is a switch operated by characteristic flat voltage determiner 155, and selects output of accumulated-charge change amount estimator 12 or output of obtainer 157.

Obtainer 157 calculates an accumulated charge change amount from an integrated current value in a voltage range determined by characteristic flat voltage determiner 155 as a flat voltage range in which the storage battery has flat charging status characteristics, the integrated current value being stored in measurement data storage 11. Obtainer 157 may obtain a charge change amount in the flat voltage range from measurement data storage 11. The integrated current value (the accumulated charge amount) or the charge change amounts stored in measurement data storage 11 are values calculated from values measured by a coulomb counter.

In this way, charging status calculator 15B calculates the total sum of accumulated charge change amounts, using the accumulated charge change amounts calculated from the values measured by the coulomb counter, rather than using accumulated charge change amounts estimated by accumulated-charge change amount estimator 12 in the flat voltage range in which the storage battery has flat charging status characteristics.

For a storage battery having the characteristics of a small voltage change relative to a change in the accumulated charge amount, when a voltage change amount in a voltage range of flat charging status characteristics is input into the estimation model, an error in an estimation result will be large. Thus, in the voltage range of flat charging status characteristics, charging status calculator 15B calculates the total sum of accumulated charge change amounts by using an integrated current value (an accumulated charge amount) or charge change amounts obtained from values measured by the coulomb counter and stored in measurement data storage 11. Thus, it is possible to use accumulated charge change amounts with higher accuracy in the voltage range of the flat charging status characteristics where an error due to error accumulation by the coulomb counter is smaller than an error in the result of estimation by the estimation model.

It should be noted that the case in which charging status calculator 15B includes characteristic flat voltage determiner 155, selector 156, and obtainer 157 is described. However, the configuration is not limited to the above configuration. Accumulated-charge change amount estimator 12 may include characteristic flat voltage determiner 155, selector 156, and obtainer 157.

### 2.3.3 Low Pass Filter 32

As described above, low pass filter 32 includes one or more low pass filters. As described above with reference to FIG. 2, low pass filter 32 includes two low pass filters having different time constants, which are voltage low pass filter 1 (voltage LPF1) and voltage low pass filter 2 (voltage LPF2). Furthermore, low pass filter 32 includes two low pass filters having different time constants, which are current low pass filter 1 (current LPF1) and current low pass filter 2 (current LPF2). Voltage low pass filter 1 may have the same time constant as current low pass filter 1. Likewise, voltage low pass filter 2 may have the same time constant as current low pass filter 2.

As long as having the effects of being able to suppress a change, any low pass filter can be used. A first-order CR filter, a second-order CR filter, and digital filters such as a moving average filter, a FIR filter, and an IIR filter can be used.

### 2.3.4 Accumulated-Charge Change Amount Machine Learner 16A

In Example 1, as illustrated in FIG. 2, accumulated-charge change amount machine learner 16A includes accumulated-charge change amount estimator 161, subtractor 162, and model updater 164.

Accumulated-charge change amount estimator 161 estimates accumulated charge change amounts by using the trained estimation model that receives, as input, first smoothed voltage values in the predetermined voltage range, voltage change amounts corresponding to the first smoothed voltage values, smoothed current values smoothed in synchronization with the first smoothed voltage values. The first smoothed voltage values and the smoothed voltage change amounts corresponding to the first smoothed voltage values are stored in measurement data storage 11. It should be noted that accumulated-charge change amount estimator 161 may estimate accumulated charge change amounts by using measurement data including the temperature at the time point when the voltage was measured, the amount of change in the temperature, and a measurement duration.

Using training data, model updater 164 updates the estimation model stored in estimation model storage 13. That is, model updater 164 trains the estimation model in accordance with training rate 163 to cause the difference between the accumulated charge change amount relative to a first-smoothed-voltage change amount estimated by the estimation model and the accumulated charge change amount included in the training data to be the smallest. Model updater 164 trains the estimation model by updating parameters, such as the weight of the estimation model, an offset value (addition value in a neural network), and a threshold (a comparison value in decision trees), by the amount corresponding to training rate 163. The amount of parameter update may be calculated using the least-squares method or various numerical-value calculation algorithms that repeats iterative processing.

In this way, accumulated-charge change amount machine learner 16A learns about how much charge inside the storage battery has changed relative to the voltage change, using the measurement data stored in measurement data storage 11. By continuously repeating the training processing, accumulated-charge change amount machine learner 16A can continuously update the estimation model.

It should be noted that the processing of accumulated-charge change amount machine learner 16A may be performed using a GPU or a dedicated component such as a semiconductor intended for machine learning.

In addition, in Example 1, accumulated-charge change amount estimator 12 estimates the accumulated charge change amount(s) by using the trained estimation model that has been updated by accumulated-charge change amount machine learner 16A and that receives, as input, one or more smoothed voltage values in the predetermined voltage range, a second smoothed voltage value, one or more smoothed current values, and a voltage change amount obtained by subtracting one of the one or more smoothed voltage values from the second smoothed voltage value.

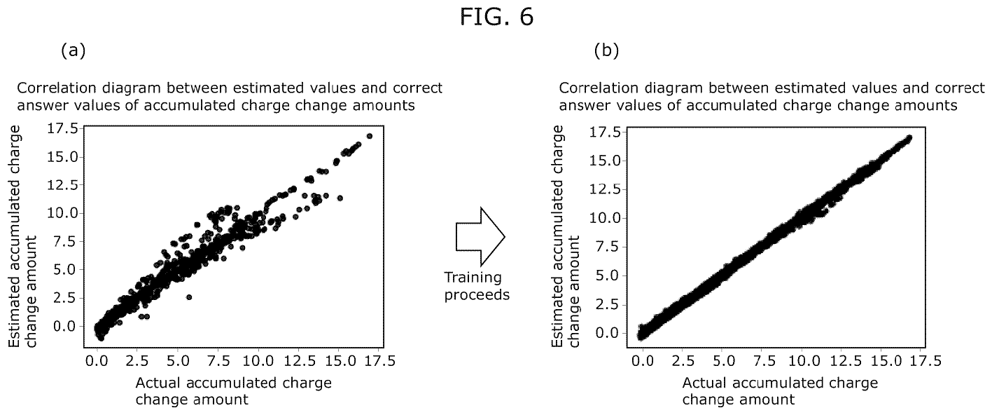

FIG. 6 illustrates diagrams before and after training which proceeds through training processing performed by accumulated-charge change amount machine learner 16A according to Example 1. (a) in FIG. 6 illustrates a correlation diagram between accumulated charge change amounts (estimated values) estimated by the estimation model prior to update through the training processing and actual accumulated charge change amounts (correct answer values) calculated using the measurement data. (b) in FIG. 6 illustrates a correlation diagram between accumulated charge change amounts (estimated values) estimated by the estimation model after the update through the training processing and the actual accumulated charge change amounts (correct answer values) calculated using the measurement data. If there is the correlation of 100%, data items are aligned from the bottom left toward the top right. Accordingly, as illustrated in (a) in FIG. 6, in the estimation model prior to the update through the training processing, the training is not sufficient enough, and variations are seen. Meanwhile, as illustrated in (b) in FIG. 6, as the training proceeds, the correlation is enhanced, and less variations are seen.

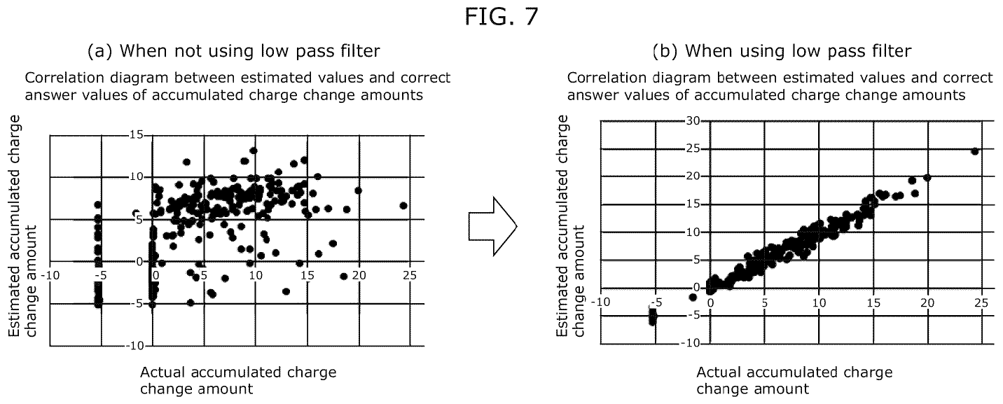

FIG. 7 is a figure for explaining the effects of the low pass filter on machine learning.

(a) in FIG. 7 illustrates a correlation diagram between accumulated charge change amounts (estimated values) estimated by the estimation model trained by machine learning using measurement data obtained without via low pass filter 32 and actual accumulated charge change amounts (correct answer values) calculated using the measurement data. (b) in FIG. 7 illustrates a correlation diagram between accumulated charge change amounts (estimated values) estimated by the estimation model trained by machine learning using measurement data obtained via low pass filter 32 and actual accumulated charge change amounts (correct answer values) calculated using the measurement data.

As understood by comparing (a) and (b) in FIG. 7, large variations are seen in (a) in FIG. 7, whereas less variations are seen in (b) in FIG. 7.

If there is a change in the current flowing through the storage battery, a change in the output voltage of the storage battery becomes larger due to the effects of the internal impedance of the storage battery. Thus, in (a) in FIG. 7, the variations are large in the estimation values of the estimation model trained by machine learning using the measurement data (voltage change amounts and accumulated charge change amounts) obtained from the output voltage whose change is large. Meanwhile, in (b) in FIG. 7, the variations are small in the estimation values of the estimation model since the estimation model was trained by machine learning using the measurement data (voltage change amounts and accumulated charge change amounts) obtained via low pass filter 32.

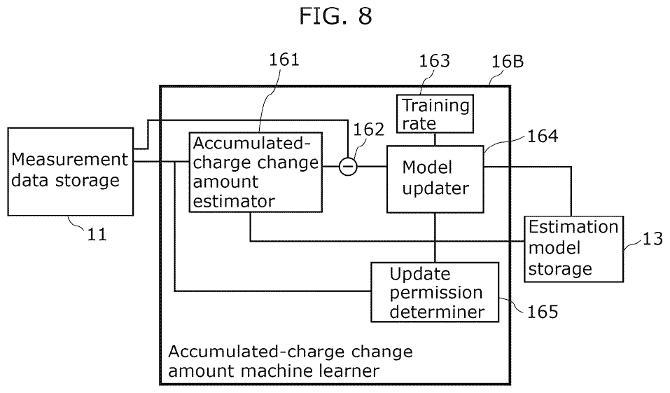

FIG. 8 illustrates another example of the configuration of the accumulated-charge change amount machine learner according to Example 1.

As illustrated in FIG. 8, accumulated-charge change amount machine learner 16B according to Example 1 includes accumulated-charge change amount estimator 161, subtractor 162, model updater 164, and update permission determiner 165. It should be noted that the elements similar to those illustrated in FIG. 2 are assigned the same reference signs and detailed explanations are omitted.

In terms of including update permission determiner 165, accumulated-charge change amount machine learner 16B in FIG. 8 has a configuration different from that of accumulated-charge change amount machine learner 16A in FIG. 2.

Update permission determiner 165 refers to the measurement data stored in measurement data storage 11 and determines whether to update the estimation model. For instance, if the measurement data includes a measurement time interval for a voltage value difference calculated as a voltage change amount, and if the measurement time interval is long, update permission determiner 165 determines not to update the estimation model. This is because an error in the accumulated charge change amount may be large.

In this way, accumulated-charge change amount machine learner 16B can reduce an error in the result of estimation by the updated estimation model.

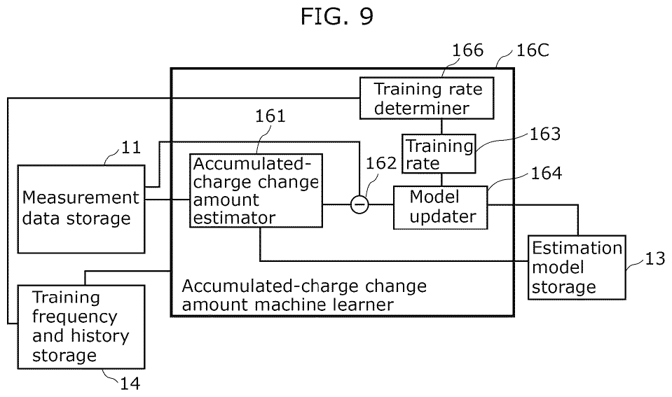

FIG. 9 illustrates still another example of the configuration of the accumulated-charge change amount machine learner according to Example 1.

As illustrated in FIG. 9, accumulated-charge change amount machine learner 16C according to Example 1 includes accumulated-charge change amount estimator 161, subtractor 162, model updater 164, and training rate determiner 166. It should be noted that the elements similar to those illustrated in FIG. 2 are assigned the same reference signs and detailed explanations are omitted.

In terms of including training rate determiner 166, accumulated-charge change amount machine learner 16C in FIG. 9 has a configuration different from that of accumulated-charge change amount machine learner 16A in FIG. 2.

It should be noted that training frequency and history storage 14 stores the training frequency indicating how often training has been performed recently, for each classification of the measurement data used in the training processing by accumulated-charge change amount machine learner 16C, for example, for each voltage range.

Training rate determiner 166 determines the training rate and updates the value of training rate 163. For instance, training rate determiner 166 refers to training frequency and history storage 14, and if the training processing is performed using past measurement data in a voltage range with a low training frequency, the value of training rate 163 is increased. Thus, in the voltage range with the low training frequency, by increasing changes in parameters inside the estimation model, training in a short training time is made possible to follow a change in the characteristics. In addition, for instance, training rate determiner 166 refers to training frequency and history storage 14, and if the training processing is performed using past measurement data in a voltage range with a high training frequency, the value of training rate 163 is decreased. Thus, in the voltage range with the high training frequency, by decreasing changes in the parameters inside the estimation model, training with higher accuracy is achieved.

In this way, accumulated-charge change amount machine learner 16C can reduce, across the entirety of voltage ranges, errors in the results of estimation by the updated estimation model.

### Another Example of Example 1

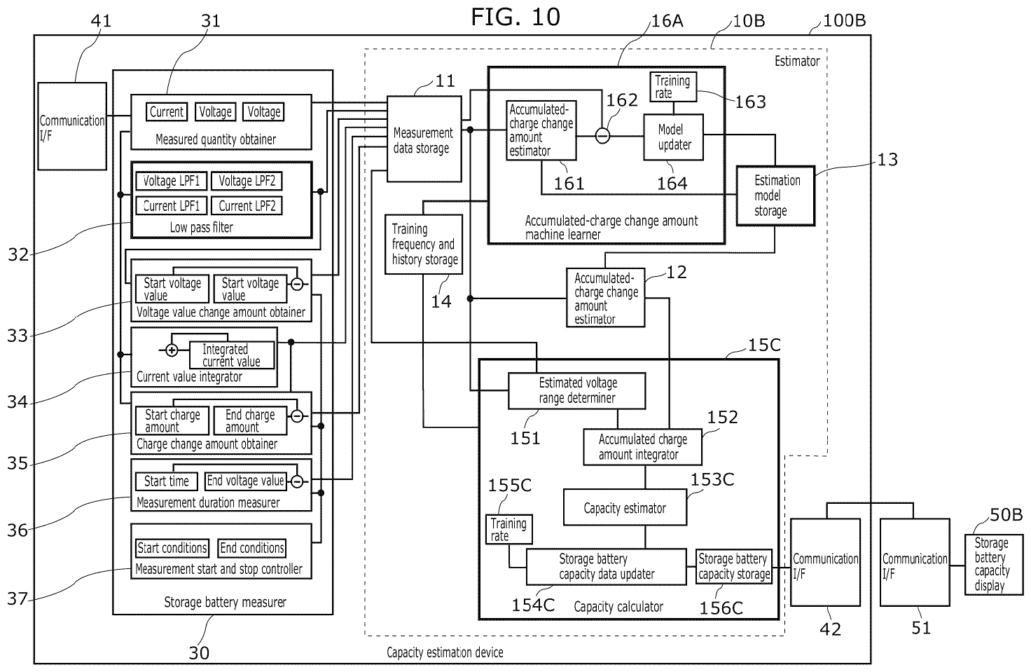

FIG. 10 illustrates another example of the configuration of the system according to Example 1.

As illustrated in FIG. 10, a system according to another example of Example 1 includes capacity estimation device 100B and storage battery capacity display 50B. It should be noted that in FIG. 10, one or more storage battery management devices 20 are omitted. In addition, the elements similar to those illustrated in FIGS. 1 and 2 are assigned the same reference signs, and detailed explanations are omitted.

### 2.4 Capacity Estimation Device 100B

Capacity estimation device 100B in FIG. 10 differs from charging status estimation device 100A in FIG. 2 in terms of estimator 10B. In addition, estimator 10B in FIG. 10 differs from estimator 10A in FIG. 2 in terms of capacity calculator 15C. Differences from Example 1 are mainly described below.

### 2.4.1.1 Accumulated-Charge Change Amount Estimator 12

As with Example 1, accumulated-charge change amount estimator 12 estimates the accumulated charge change amount by using the estimation model that has learned through machine learning and that receives, as input to the estimation model that has learned, one or more first smoothed voltage values in the predetermined voltage range, one or more smoothed current values measured and smoothed in synchronization with the one or more first smoothed voltage values, and a voltage change amount obtained by subtracting one of the one or more first smoothed voltage values from a second smoothed voltage value. Here, the predetermined voltage range is determined by capacity calculator 15C, which is described later.

### 2.4.1.2 Capacity Calculator 15C

Capacity calculator 15C calculates the total sum of accumulated charge change amounts in the predetermined voltage range, divides the total sum by the total sum of accumulated charge change amounts in the predetermined voltage range in the storage battery with known capacity, and multiples the result of the division by the known capacity of the storage battery, to calculate the capacity of the storage battery to be calculated.

It should be noted that capacity calculator 15C is a specific example of calculator 15 in the embodiment.

In the present example, as illustrated in FIG. 10, capacity calculator 15C includes estimated voltage range determiner 151, accumulated charge amount integrator 152, capacity estimator 153C, storage battery capacity data updater 154C, and storage battery capacity storage 156C. It should be noted that storage battery capacity data updater 154C is not an essential element. The elements similar to those illustrated in FIG. 2 are assigned the same reference signs, and detailed explanations are omitted.

Accumulated charge amount integrator 152 calculates the total sum of accumulated charge change amounts in the predetermined voltage range.

Capacity estimator 153C divides the total sum calculated by accumulated charge amount integrator 152 by the total sum in the storage battery with known capacity and multiplies the result of the division by the known capacity of the storage battery, to calculate the capacity of the storage battery.

In accordance with training rate 155C, storage battery capacity data updater 154C updates the capacity of the storage battery previously estimated by storage battery capacity data updater 154C to the capacity of the storage battery estimated by capacity estimator 153C. Thus, taking advantage of the characteristic that the capacity of the storage battery changes over time, it is possible to reduce, by averaging, errors in a voltage change amount calculated from voltage values, which are measured values, and errors in estimation by the estimation model. That is, even if there is a change in the characteristics of the storage battery, by updating, that is, using machine learning, storage battery capacity data updater 154C can reduce an error in the capacity of the storage battery estimated by capacity estimator 153C and update the capacity of the storage battery to more correct capacity.

Storage battery capacity storage 156C includes semiconductor memory and stores the capacity of the storage battery updated by storage battery capacity data updater 154C.

As described above, capacity calculator 15C can calculate the capacity of the storage battery as the battery status.

### 2.5 Effects of Example 1

Unlike the conventional techniques in which the battery status is obtained directly from the charge amount of a coulomb counter or the voltage value of a storage battery, charging status estimation device 100A according to Example 1 calculates the charge change amount of the storage battery via the estimation model trained by machine learning, on the basis of the smoothed voltage value(s) of the storage battery, the amount(s) of change in the smoothed voltage value (smoothed voltage change amount(s)), and smoothed current value(s). Accordingly, charging status estimation device 100A according to Example 1 can obtain the battery status of the storage battery as the result of estimation, by estimating accumulated charge change amount(s) with the use of the trained estimation model from smoothed voltage change amount(s) calculated from the measured values of voltages measured when the storage battery is charged or discharged.

In this way, charging status estimation device 100A according to Example 1 can calculate the charging status such as the capacity of the storage battery, by estimating accumulated charge change amounts from voltage change amounts with the use of the estimation model and integrating the estimated accumulated charge change amounts. Thus, the training data need not include the charging status of the storage battery, which means that the training data can be obtained in a short time and at a low cost. Furthermore, since the effects of an error in the result of measurement by the current sensor are lessen and the issue of error accumulation in the accumulated charge can be avoided, the charging status of the storage battery as the battery status of the storage battery can be estimated with higher accuracy. In addition, by using one or more smoothed voltage values and one or more smoothed current values, it is possible to suppress the effects on the measurement of a change in the current during charging or discharging, and respond to the various usage states of the storage battery with the use of the same estimation model.

Furthermore, by continuously training the estimation model by machine training, following a change in the characteristics of the storage battery and the individual difference of the storage battery is made possible. This enables estimation of the battery status reflecting the followed degradation and individual difference of the storage battery.

### Example 2

In Example 2, a case in which the battery status of the storage battery is the degradation level of the storage battery is described.

### 3 Configuration of System According to Example 2

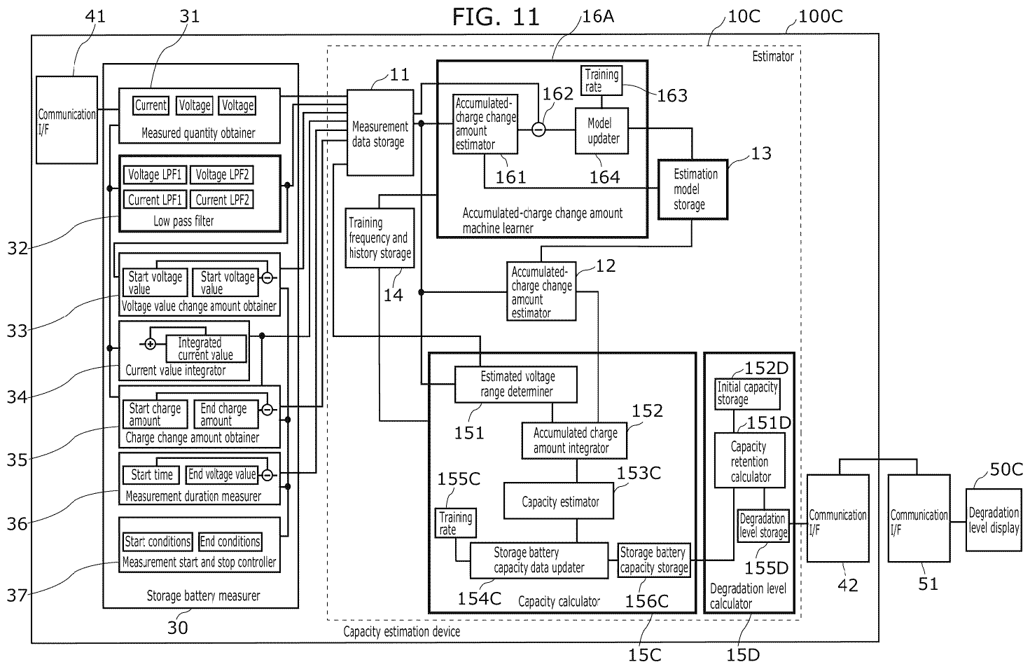

FIG. 11 illustrates an example of a configuration of a system according to Example 2.

As illustrated in FIG. 11, the system according to Example 2 includes capacity estimation device 100C and degradation level display 50C. It should be noted that in FIG. 11, one or more storage battery management devices 20 are omitted. In addition, the elements similar to those illustrated in FIG. 10 are assigned the same reference signs, and detailed explanations are omitted.

### 3.1 Degradation Level Display 50C

Degradation level display 50C includes a display. Degradation level display 50C obtains, via communication I/F51, the degradation level of a storage battery calculated by capacity estimation device 100C, and displays the obtained degradation level of the storage battery.

### 5.2 Capacity Estimation Device 100C

Capacity estimation device 100C in FIG. 11 differs from capacity estimation device 100B in FIG. 10 in terms of the configuration of estimator 10C.

### 5.2.1 Estimator 10C

As illustrated in FIG. 11, estimator 10C includes measurement data storage 11, accumulated-charge change amount estimator 12, estimation model storage 13, training frequency and history storage 14, capacity calculator 15C, accumulated-charge change amount machine learner 16A, and degradation level calculator 15D.

Estimator 10C in FIG. 11 differs from estimator 10B in FIG. 10 in terms of further including degradation level calculator 15D. It should be noted that capacity calculator 15C and degradation level calculator 15D are specific examples of calculator 15 described in the embodiment. Differences from Example 1 are mainly described below.

As the battery status, degradation level calculator 15D calculates the degradation level of the storage battery from the rate of the capacity of the storage battery calculated by capacity calculator 15C to the initial capacity of the storage battery. As illustrated in FIG. 11, degradation level calculator 15D includes capacity retention calculator 151D, initial capacity storage 152D, and degradation level storage 155D.

Initial capacity storage 152D includes semiconductor memory and stores the initial capacity of the storage battery. It should be noted that the initial capacity of the storage battery may be the design capacity value of the storage battery.

Capacity retention calculator 151D divides the present capacity of the storage battery obtained by storage battery capacity storage 156C of capacity calculator 15C, by the initial capacity stored in initial capacity storage 152D, to obtain the degradation level.

As described above, in estimator 10C, by just adding degradation level calculator 15D to estimator 10B, it is possible to obtain the degradation level of the storage battery as the battery status.

Since estimator 10C continuously updates the estimation model by using accumulated-charge change amount machine learner 16A and follows a change in the characteristics of the storage battery, estimator 10C can obtain the latest degradation level.

### Possibility of Other Embodiments

Thus, the estimation devices and the systems in the present disclosure are described above in the embodiment, examples, and the variations. However, a subject or a device that undergoes each processing is not limited to a particular subject or device.

It should be noted that the present disclosure is not limited to the above embodiment, examples, and variations. For instance, the present disclosure may include, as embodiments, an embodiment obtained by optionally combining the structural element described in the specification and an embodiment achieved by removing some of the structural elements described in the specification. In addition, the present disclosure may include a variation obtained by making various changes envisioned by those skilled in the art to the above embodiment within the scope of the present disclosure, that is, within the meanings indicated by the words recited in the claims.

In addition, the present disclosure also includes the cases described below.

(1) The device including estimator 10A described above may be at a location different from the locations of storage battery measurer 30 and storage battery management device 20.

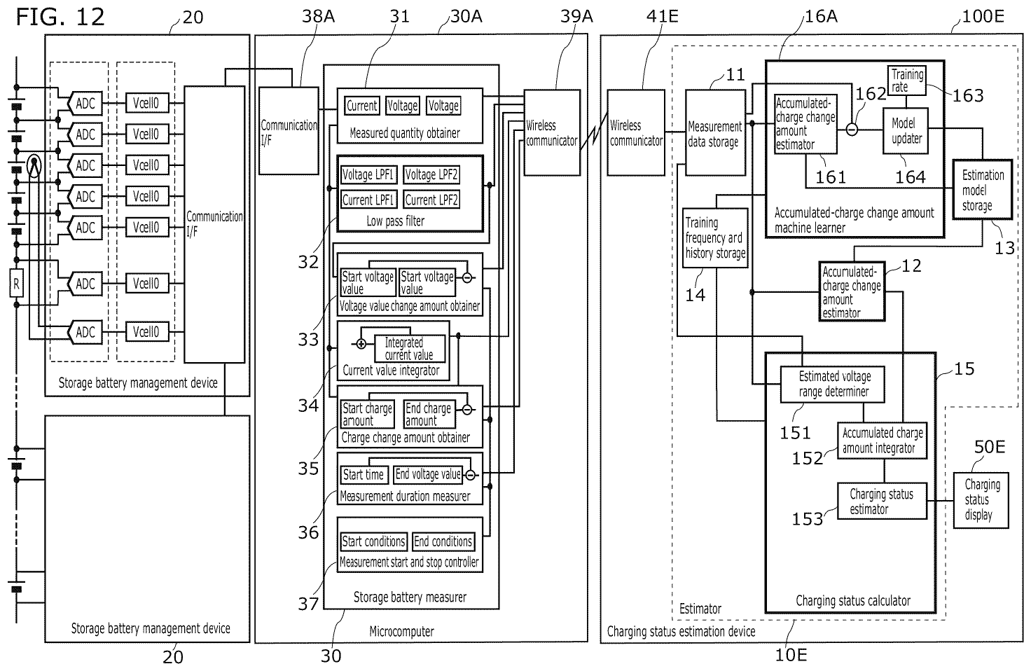

FIG. 12 illustrates an example of a configuration when charging status estimation device 100E and microcomputer 30A that includes storage battery measurer 30 are at different locations. It should be noted that the elements similar to those illustrated in FIG. 2 are assigned the same reference signs and detailed explanations are omitted.

As illustrated in FIG. 12, charging status estimation device 100E includes estimator 10E, wireless communicator 41E, and charging status display 50E.

Wireless communicator 41E is communication I/F that is wirelessly communicably connected to a network.

Estimator 10E is at a location different from the locations of storage battery management device 20 and storage battery measurer 30, and has a configuration similar to that of estimator 10A. It should be noted without being limited to having the configuration of estimator 10A, estimator 10E may include either one of the configurations of estimator 10B and estimator 10C. Estimator 10E obtains, via wireless communicator 41E, measurement data including smoothed voltage values, current values, and smoothed current values obtained when the storage battery is charged or discharged and voltage change amounts for the respective smoothed voltage values, and stores the obtained measurement data in measurement data storage 11. It should be noted that the temperature and the measurement duration when the voltage is measured may be obtained and stored in measurement data storage 11.

Since charging status display 50E has a configuration similar to that of charging status display 50, an explanation for the configuration is omitted. According to the configuration of estimator 10E, the configuration of charging status display 50E may be changed to a configuration similar to that of storage battery capacity display 50B or degradation level display 50C.

Microcomputer 30A includes storage battery measurer 30, communication I/F38A, and wireless communicator 39A. Since communication I/F38A has a configuration similar to that of communication I/F41 described above, an explanation for the configuration is omitted. Wireless communicator 39A is communication I/F that is wirelessly communicably connected to a network. Microcomputer 30A outputs measurement data to charging status estimation device 100E via wireless communicator 39A, the measurement data including smoothed voltage values measured when the storage battery is charged or discharged and voltage change amounts for the respective smoothed voltage values.

Thus, microcomputer 30A on a storage-battery-measurement-device side is at a location different from that of charging status estimation device 100E, and can be connected to charging status estimation device 100E via wireless communication, which can suppress the cost required for having the configuration of the storage-battery-measurement-device side.

Incidentally, the storage battery has a slow capacity change or a slow degradation rate. This makes it possible to decrease the frequency of machine learning or estimation, which enables provision of microcomputer 30A on the storage-battery-measurement-device side and charging status estimation device 100E at different locations, that is, at remote locations.

It should be noted that charging status estimation device 100E may be included in a cloud server. According to the above explanation, microcomputer 30A is connected to charging status estimation device 100E via wireless communication. However, the connection is not limited to the wireless communication, and if it is feasible at remote locations, microcomputer 30A and charging status estimation device 100E may be connected to each other via a wired communication such as an optical fiber communication or an Ethernet communication may be used.

(2) Only storage battery management device 20 for measuring the storage battery may be remotely located.

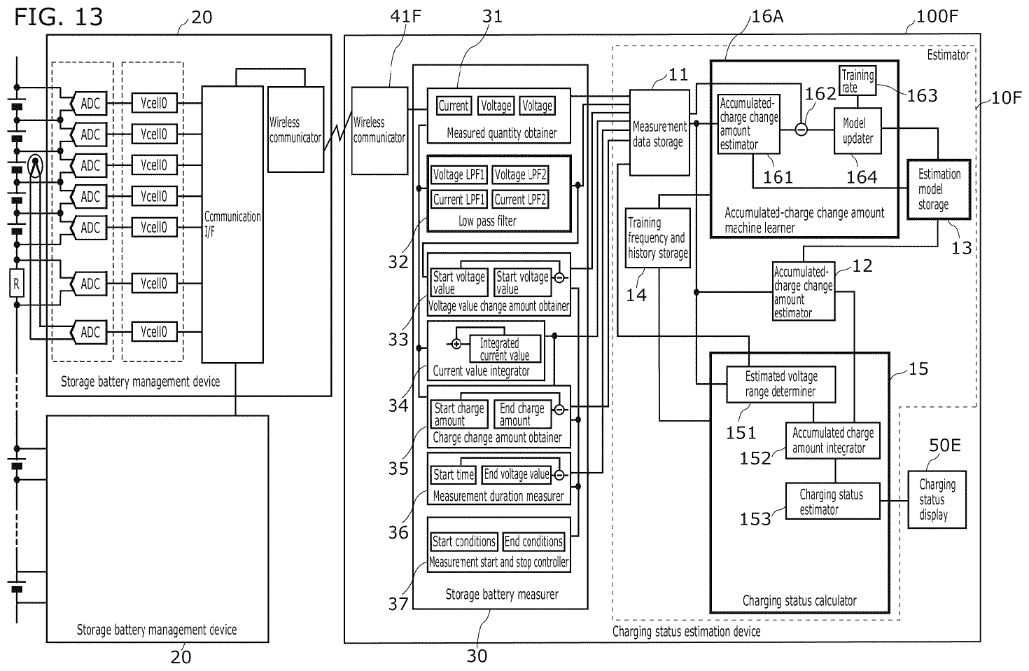

FIG. 13 illustrates an example of a configuration when charging status estimation device 100F and storage battery management devices 20 are at different locations. It should be noted that the elements similar to those illustrated in FIG. 12 and other figures are assigned the same reference signs and detailed explanations are omitted.

As illustrated in FIG. 13, charging status estimation device 100F includes estimator 10F, storage battery measurer 30, wireless communicator 41F, and charging status display 50E.

Wireless communicator 41F is communication I/F that is wirelessly communicably connected to a network.

Estimator 10F obtains a measured quantity such as a current value or a voltage value measured when the storage battery is charged or discharged, from storage battery management device 20 via wireless communicator 41F.

Storage battery management device 20 charges or discharges the storage battery and measures the measured quantity such as the current value or the voltage value. Storage battery management device 20 outputs the measured quantity to estimator 10F via wireless communicator 41F.

Typically, the storage battery does not degrade instantaneously. Thus, if the device that estimates the battery status of the storage battery is separated from the device that measures the storage battery in terms of time or space, the advantages of the present disclosure are not impaired. In addition, it is possible to reduce costs by providing a system in which the functions of the elements thereof are dispersed, depending on the device that uses the storage battery or the usage environment of the storage battery.

(3) One or more or all of the structural elements of the above estimation device and system may be included in one system large scale integration (LSI). The system LSI is a super-multifunctional LSI that is manufactured by integrating a plurality of elements into one chip, and more specifically a computer system including a microprocessor, ROM, and RAM. The RAM stores a computer program. The function of the system LSI is achieved by the microprocessor operating in accordance with the computer program.

(4) One or more or all of the structural elements included in the above device may be an IC card or a single module attachable to/detachable from each device. The IC card or the module is a computer system including a microprocessor, ROM, and RAM. The IC card or the module may include the super-multifunctional LSI described above. The function of the IC card or the module is achieved by the microprocessor operating in accordance with the computer program. The IC card or module may be tamper resistant.

(5) The present disclosure may be a computer system including a microprocessor and memory. Here, the memory may store the above computer program, and the microprocessor may operate in accordance with the computer program.

Although only an exemplary embodiment of the present disclosure has been described in detail above, those skilled in the art will readily appreciate that many modifications are possible in the exemplary embodiment without materially departing from the novel teachings and advantages of the present disclosure. Accordingly, all such modifications are intended to be included within the scope of the present disclosure.

### INDUSTRIAL APPLICABILITY

The present disclosure is applicable to an estimation device that estimates the battery status of a storage battery and a system including the estimation device. The present disclosure is applicable to applications for use in, for example, control devices included in an electric motorcycle, an electrified vehicle, an electric ship, an electric aircraft, a large-scale energy storage system, an agricultural electric machine, a drone, a logistics robot, a traveling object, and other devices. Here, the control devices continuously use storage batteries for a long time or a long period and, if the storage batteries ran out of power, give significant effects on the performance of tasks or operation of the devices.

1. A storage battery capacity estimation device that estimates a capacity of a storage battery, the storage battery capacity estimation device comprising:
a measurement data storage storing a plurality of measurement data items including:
one or more first smoothed voltage values of the storage battery obtained by smoothing one or more voltage values measured during at least one of charging or discharging of the storage battery;
a smoothed voltage change amount obtained by subtracting one of the one or more first smoothed voltage values from a second smoothed voltage value of the storage battery obtained by smoothing a voltage value further measured during the at least one of charging or discharging of the storage battery;
one or more current values of the storage battery measured in synchronization with measurement of at least one of: the one of the one or more first smoothed voltage values or the second smoothed voltage value; and
one or more smoothed current values obtained by smoothing the one or more current values;
an accumulated-charge change amount estimator that estimates an accumulated charge change amount by using an estimation model that has learned through machine learning and that receives, as input to the estimation model that has learned, one or more first smoothed voltage values in a predetermined voltage range, a smoothed voltage change amount corresponding to one of the one or more first smoothed voltage values in the predetermined voltage range, and one or more smoothed current values;
an accumulated-charge change amount machine learner that updates the estimation model by using, as input, the one or more first smoothed voltage values in the predetermined voltage range, the smoothed voltage change amount corresponding to the one of the one or more first smoothed voltage values, and the one or more smoothed current values out of the plurality of measurement data items and using, as correct answer data, an accumulated charge change amount obtained by integrating current values measured during obtainment of the smoothed voltage change amount; and
a calculator that calculates a total sum of accumulated charge change amounts in the predetermined voltage range estimated by the accumulated-charge change amount estimator, and obtains the capacity of the storage battery according to the total sum calculated, the accumulated charge change amounts each being the accumulated charge change amount.

2. The storage battery capacity estimation device according to claim 1, further comprising:
a degradation level calculator that estimates a degradation level of the storage battery from a proportion of the capacity of the storage battery to an initial capacity of the storage battery.

3. A system comprising:
the storage battery capacity estimation device according to claim 1; and
a capacity management device that measures the plurality of measurement data items through at least one of charging or discharging of the storage battery, wherein
the storage battery capacity estimation device and the capacity management device are disposed at different locations, and
the storage battery capacity estimation device obtains, via a communication network, the plurality of measurement data items obtained by the storage battery management device, and stores the plurality of measurement data items in the measurement data storage.

4. A system comprising:
the storage battery capacity estimation device according to claim 2; and
a storage battery management device that measures the plurality of measurement data items through at least one of charging or discharging of the storage battery, wherein
the storage battery capacity estimation device and the capacity management device are disposed at different locations, and
the storage battery capacity estimation device obtains, via a communication network, the plurality of measurement data items obtained by the storage battery management device, and stores the plurality of measurement data items in the measurement data storage.
